(19) United States
(12) Patent Application Publication
(10) Pub. No.: US 2025/0277304 A1
(43) Pub. Date: Sep. 4, 2025

(54) FILM FORMING APPARATUS

(71) Applicant: Resonac Hard Disk Corporation, Chiba (JP)

(72) Inventor: Gohei KUROKAWA, Chiba (JP)

(21) Appl. No.: 19/065,237

(22) Filed: Feb. 27, 2025

(30) Foreign Application Priority Data
Mar. 4, 2024 (JP) 2024-031935

(51) Int. Cl. C23C 14/50; C23C 14/56

(52) U.S. Cl. CPC C23C 14/505; C23C 14/568

(57) ABSTRACT

In a film-forming apparatus, a transport mechanism that transports a carrier includes a support unit provided in a chamber and configured to support the carrier. The support unit includes a plurality of rotating members that support the carrier, and extends from an upstream side to a downstream side in a transport direction of the carrier. The plurality of rotating members are arranged in a row from the upstream side to the downstream side of the support unit. Each of the rotating members includes a rotating member outer peripheral portion having an annular shape, a bearing provided inside the rotating member outer peripheral portion, and a buffer member provided between an inner peripheral surface of the rotating member outer peripheral portion and an outer peripheral surface of the bearing.

### CROSS-REFERENCE TO RELATED APPLICATIONS

Priority is claimed to Japanese Patent Application No. 2024-031935, filed Mar. 4, 2024, the entire content of which is incorporated herein by reference.

### BACKGROUND

### 1. Technical Field

The present disclosure relates to a film-forming apparatus.

### 2. Description of Related Art

Conventionally, a film-forming apparatus is known which performs a film forming process on a substrate by sequentially transporting a carrier holding the substrate into a plurality of chambers (see Japanese Unexamined Patent Publication No. H8-274142, hereinafter “Patent Document 1”). Such a film-forming apparatus often has a structure in which a plurality of chambers are connected via a gate valve, and the carrier vibrates in the vertical direction when passing through the gate valve, and the substrate may be damaged or may fall due to the vibration.

Japanese Unexamined Patent Publication No. 2010-33645 (hereinafter “Patent Document 2”) discloses a film-forming apparatus capable of reducing an impact applied to a carrier when the carrier passes between chambers connected via a gate valve. As a configuration for reducing an impact, a buffer mechanism in which a cylindrical elastic member is arranged between a support shaft supporting a main bearing, which is a guide mechanism for guiding the carrier, and a shaft hole, or a buffer mechanism in which a plurality of O-rings are arranged side by side in an axial direction is described.

### SUMMARY

A film-forming apparatus according to an aspect of the present invention includes: a carrier configured to hold a substrate; a plurality of chambers configured to perform a film forming process on the substrate; a vacuum pump configured to decompress an inside of at least one of the plurality of chambers; a gate valve configured to make the chamber a sealed space; and a transport mechanism configured to transport the carrier into the gate valve and the plurality of chambers. At least one of the plurality of chambers includes a heating mechanism for the substrate. The transport mechanism includes a support unit provided in the chamber and configured to support the carrier. The support unit includes a plurality of rotating members that support the carrier, and extends from an upstream side to a downstream side in a transport direction of the carrier. The plurality of rotating members are arranged in a row from the upstream side to the downstream side of the support unit. Each of the rotating members includes a rotating member outer peripheral portion having an annular shape, a bearing provided inside the rotating member outer peripheral portion, and a buffer member provided between an inner peripheral surface of the rotating member outer peripheral portion and an outer peripheral surface of the bearing.

### BRIEF DESCRIPTION OF THE DRAWINGS

FIG. 1 is a plan view of a film-forming apparatus according to an embodiment;

FIG. 2 is a cross-sectional view of a recording medium manufactured by the film-forming apparatus according to the embodiment;

FIG. 3 is a side sectional view of chambers in the film-forming apparatus according to the embodiment;

FIG. 4A is a side view of a carrier of the film-forming apparatus according to the embodiment;

FIG. 4B is a front view of the carrier of the film-forming apparatus according to the embodiment;

FIG. 5 is a side view of a supporting unit according to the embodiment;

FIG. 6 is a plan view of a supporting unit according to the embodiment; and

FIG. 7 is a cross-sectional view of a supporting unit according to the embodiment.

### DETAILED DESCRIPTION

In the inline film-forming apparatus disclosed in Patent Document 2, since the plurality of O-rings as the buffer member are arranged between the support shaft supporting the main bearing and the shaft hole, a moment applied to the buffer member is increased. It is therefore difficult to maintain the positional accuracy of the main bearing due to deformation of the buffer member. It is conceivable to increase the stiffness of the buffer member in order to suppress deformation of the buffer member; however, there are only a few types of buffer members that can be used in a vacuum environment, and this limits the range of stiffness that can be selected to a certain stiffness or higher. If the stiffness of the buffer member is increased, the buffering property is lost, and it becomes difficult to reduce the vibration applied to the main bearing.

In view of the above problems, it is an object of the technology of the present disclosure to provide a film-forming apparatus capable of suppressing damage or falling of a substrate while maintaining the positional accuracy of a rotating member that conveys a carrier.

Hereinafter, embodiments of the present disclosure will be described in detail with reference to the drawings. In the drawings, the same components are denoted by the same reference numerals, and redundant description will be appropriately omitted.

### Configuration Example of Film Forming Apparatus

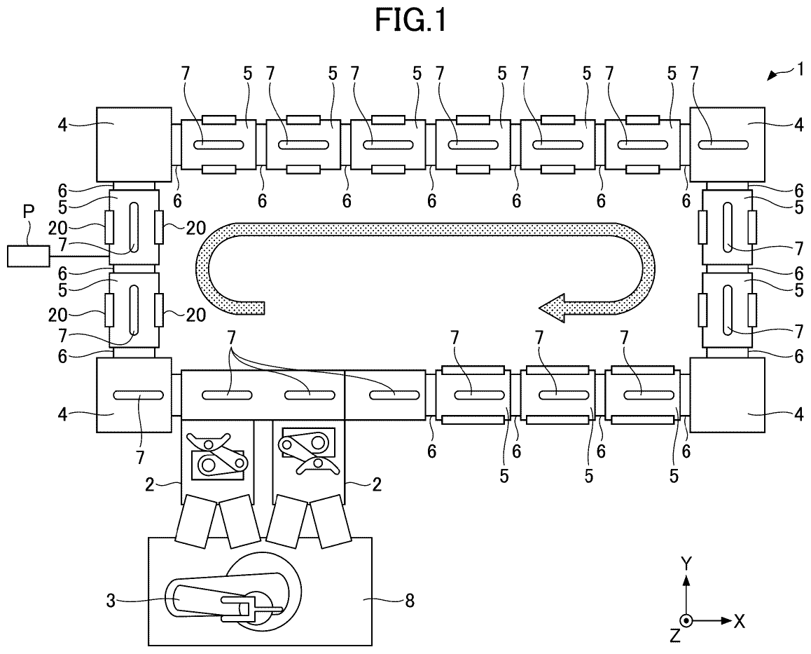

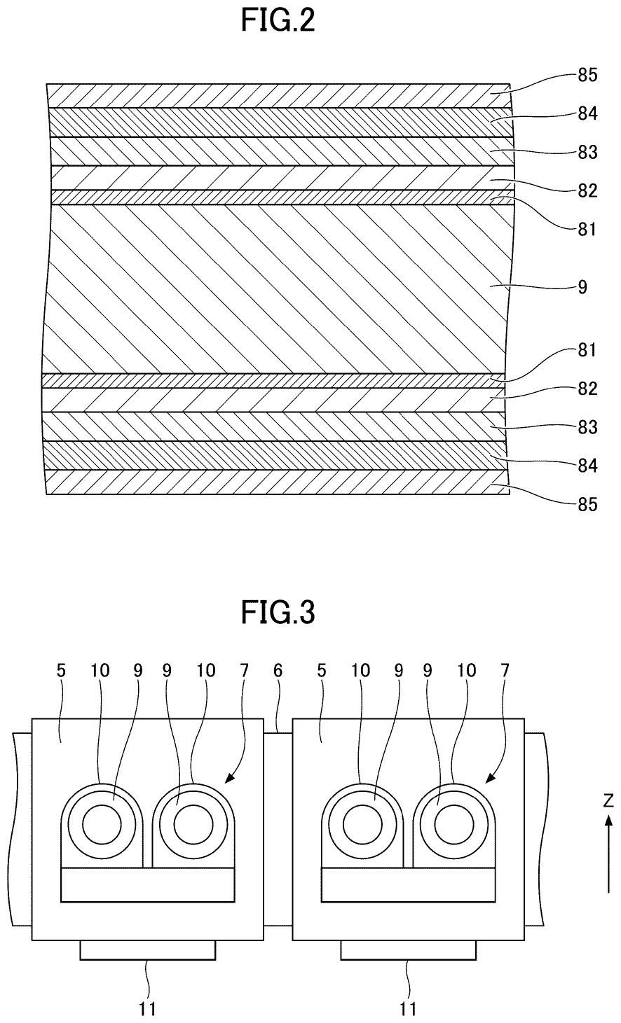

FIG. 1 is a plan view of a film-forming apparatus according to an embodiment, FIG. 2 is a cross-sectional view of a recording medium manufactured by the film-forming apparatus according to the embodiment, and FIG. 3 is a side view of a chamber 5 of the film-forming apparatus according to the embodiment. In the present embodiment, a case where the film-forming apparatus 1 is an inline film-forming apparatus will be described as an example.

In general, a sputtering method, a CVD method, a PVD method, or the like is used for forming each layer of the recording medium, and in many cases, film formation with each method is performed after the inside of a film-forming apparatus is brought into a vacuum state and a processing gas is introduced into the film-forming apparatus. In addition, the substrate is often heated before and after the formation of each layer, and the heating temperature may reach 600° C. In the case of such a manufacturing method, it is preferable to continuously perform the manufacturing method using a single film-forming apparatus as much as possible.

The inline film-forming apparatus can suppress contamination of a substrate during handling by continuously performing film formation processing, and can improve the efficiency of a manufacturing process and the yield of a product by reducing the number of handling processes, etc., thereby increasing the productivity in manufacturing the recording medium.

The recording medium is, for example, a magnetic recording medium. When manufacturing a magnetic recording medium, for example, at least a soft magnetic layer 81, an intermediate layer 82, a recording magnetic layer 83, and a protective layer 84 are sequentially laminated, as illustrated in FIG. 2, on respective surfaces of a substrate 9 to be subjected to film formation using a film-forming apparatus 1 like the one illustrated in FIG. 1. A lubricating film 85 may be further laminated on the outermost surfaces. Through such a process, the magnetic recording medium can be obtained at high productivity, according to the film-forming apparatus 1.

The substrate 9 may be, for example, a disk-shaped substrate. As the substrate 9, an Al alloy substrate such as an Al—Mg alloy containing Al as a main component, a substrate made of any one of ordinary soda glass, aluminosilicate-based glass, crystallized glass, silicon, titanium, ceramics, various resins, and the like is used. In other words, the substrate 9 may be any non-magnetic substrate.

The film-forming apparatus 1 includes a robot base 8, a substrate cassette transfer robot 3 placed on the robot base 8, a substrate attaching/detaching robot 2 adjacent to the robot base 8, and a plurality of corner chambers 4 for rotating carriers 7. As illustrated in FIGS. 1 and 3, the film-forming apparatus 1 includes a plurality of chambers 5 arranged between the corner chambers 4 for performing a film forming process on the substrate 9, a plurality of carriers 7 for holding the substrate 9 and sequentially transported through the plurality of corner chambers 4 and the plurality of chambers 5, and a processing mechanism 20 for processing both surfaces of the substrate 9. In FIG. 1, the processing mechanisms 20 are provided in all the chambers 5, but the reference numeral 20 is partially omitted.

The film-forming apparatus 1 further includes a vacuum pump P that depressurizes the inside of at least one of the plurality of chambers 5, and a gate valve 6 that makes the inside of the chamber 5 a sealed space. In the example illustrated in FIG. 1, the gate valve 6 is provided at a connecting portion of each chamber 5, and when each gate valve 6 is in a closed state, the inside of each chamber 5 becomes an independent sealed space. A vacuum pump P may be connected to each of the chambers 5, and the inside of each of the chambers 5 is brought into a decompressed state by the operation of the vacuum pump P. At least one of the plurality of chambers 5 includes a heating mechanism for the substrate 9 as the processing mechanism 20.

Sequentially transporting the carrier 7 into each chamber 5 by the transport mechanism 11 (described later), the film-forming apparatus 1 sequentially forms the soft magnetic layer 81, the intermediate layer 82, the recording magnetic layer 83, and the protective layer 84 on respective surfaces of the substrate 9 held by the carrier 7 in each chamber 5, using the processing mechanism 20. After the protective layer 84 is formed on the substrate 9, the substrate 9 is taken out from the film-forming apparatus 1, and the lubricating film 85 is formed on respective surfaces of the substrate 9, thereby finally obtaining the magnetic recording medium illustrated in FIG. 2.

Each corner chamber 4 is a chamber for changing the moving direction of the carrier 7, and a mechanism for rotating the carrier 7 to move it to the next chamber 5 is provided inside the corner chamber 4.

As illustrated in FIG. 3, the film-forming apparatus 1 includes a transport mechanism 11 configured to transport the carrier 7 into the gate valve 6 and the chamber 5. The transport mechanism 11 includes, for example, a linear motor drive mechanism that is driven in a non-contact state.

In this linear motor driving mechanism, a plurality of magnets are arranged below the carrier 7 in such a manner that N poles and S poles are alternately arranged, and rotary magnets whose N pole and S pole are alternately arranged in a spiral shape are arranged along the transport path below the magnets with a partition wall being interposed between the magnets below the carrier 7 and the rotary magnets. The linear motor drive mechanism transports the carrier 7 by rotating the rotary magnets around the axis while magnetically coupling the magnets on the carrier 7 side and the rotary magnets in a non-contact manner.

### Configuration Example of Carrier

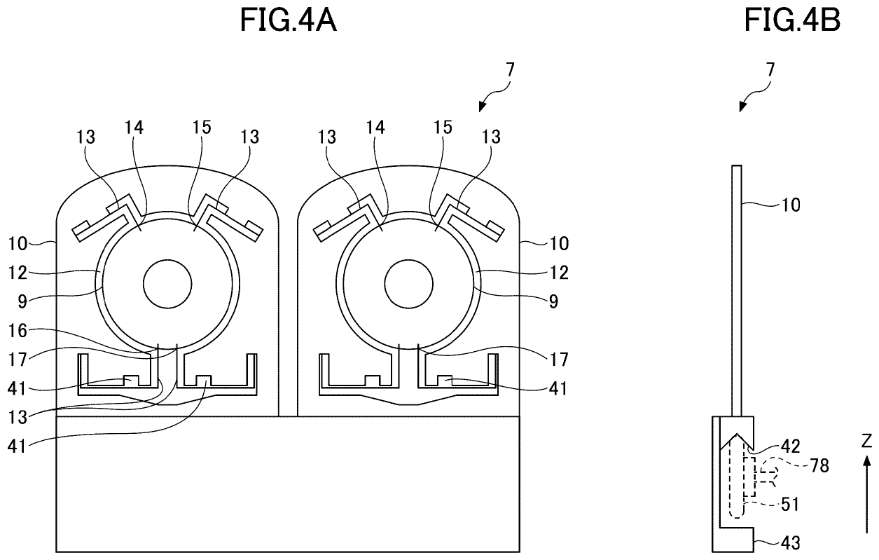

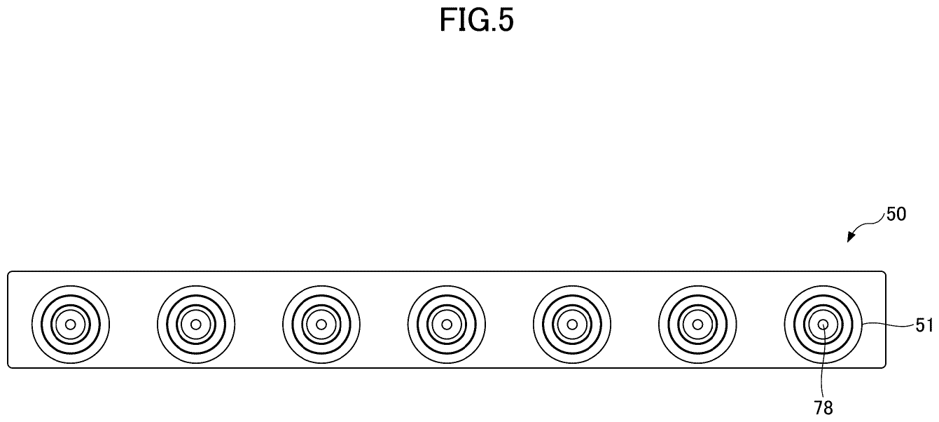

FIG. 4A is a side view of the carrier 7 of the film-forming apparatus according to the embodiment, and FIG. 4B is a front view of the carrier 7 of the film-forming apparatus according to the embodiment. The carrier 7 is provided with one substrate holder 10 for holding the substrate 9 in a vertical position. The vertical placement means a state in which the main surface (front surface or rear surface) of the substrate 9 is parallel to the vertical direction. In the present embodiment, two substrate holders 10 are arranged on the carrier 7, but the number of substrate holders 10 provided on the carrier 7 is not limited.

The substrate holder 10 holds the substrate 9 in the hole 12 in a detachable manner. The substrate holder 10 may include a substrate holder 10 provided with the hole 12 in which the substrate 9 is arranged, and a plurality of support members 13 attached around the hole 12 of the substrate holder 10 so as to be elastically deformable. The plurality of support members 13 abut on the outer peripheral edge portion of the substrate 9 and support the substrate 9 fitted into the hole 12. In the present embodiment, four support members 13 are attached to the substrate holder 10, but three or more support members 13 suffice to support the substrate 9.

Among the four support members 13, two support members 13 positioned in the upper side in the vertical direction Z respectively support a first side outer peripheral edge portion 14, which is positioned in the upstream side in the transport direction of the carrier 7, and a second side outer peripheral edge portion 15, which is positioned in the downstream side in the transport direction of the carrier 7. Two support members 13 positioned in the lower side in the vertical direction Z among the four support members 13 respectively support a third side outer peripheral edge portion 16, which is positioned in the upstream side in the transport direction of the carrier 7, and a fourth side outer peripheral edge portion 17, which is positioned in the downstream side in the transport direction of the carrier 7.

The support member 13 is a plate spring member that is bent in an L shape or a U shape, for example. The proximal end side of the support member 13 is fixed to the main body of the substrate holder 10, and the distal end side of the support member 13 protrudes toward the inside of the hole portion 12. The support member 13 is arranged in a passage formed around the hole 12. At the distal end of the support member 13, a V-shaped groove or a U-shaped groove is formed to engage with the outer peripheral edge portion of the substrate 9 in order to prevent the substrate 9 from falling.

Among the four passages formed around the hole 12, two lower passages in the lower side are respectively provided with a release hole 41 for releasing the support of the substrate 9 by the support member 13. A release rod (not illustrated) for releasing the support of the substrate 9 by the support member 13 by pushing the support member 13 downward is inserted into each of two release holes 41.

The substrate 9 is attached to and detached from the substrate holder 10 by the substrate attaching/detaching robot 2, such as an articulated robot. To attach the substrate 9, the substrate attaching/detaching robot 2 inserts the substrate 9 suspended by a substrate holding member (not illustrated) into the hole 12 of the substrate holder 10, with two release rods being respectively inserted into the two release holes 41 to push down the two lower support members 13. Then, by releasing the pressing of the support members 13 by the two release rods, the lower support member 13 returns to the original position, and the four support members 13 support the substrate 9.

To detach the substrate 9, the substrate attaching/detaching robot 2 inserts the substrate holding member into the opening of the substrate 9 while avoiding contact between the substrate holding member and the substrate 9. Then, two release rods are respectively inserted into the two release holes 41 to push down the two lower support members 13, thereby releasing the support of the substrate 9 by the four support members 13, so that the substrate attaching/detaching robot 2 suspends the substrate 9 from the substrate holding member. The substrate attaching/detaching robot 2 detaches the substrate 9 from the substrate holder 10 while avoiding collision of the substrate 9 with the support member 13.

As illustrated in FIG. 4B, the carrier 7 is provided with a supported surface 42 that is supported from the lower side in the vertical direction Z by a plurality of rotating members 51. Specifically, the supported surface 42 is supported by a flange portion 722, which will be described later, from the lower side of the vertical direction Z. The supported surface 42 extends along the conveying direction of the carrier 7 and is formed in a rail shape. The cross-sectional shape of the supported surface 42 is a shape into which the rotating members 51 supporting the carrier 7 from the lower side of the vertical direction Z is fitted, and is, for example, an inverted V shape or an inverted U shape. The outer peripheral surface of the upper end of the rotating member 51 in the vertical direction Z comes into contact with the supported surface 42 when the carrier 7 is conveyed.

A linear motor driving unit 43 in which a plurality of magnets are arranged such that N poles and S poles are alternately arranged is provided as a part of a linear motor driving mechanism below the carrier 7. In the present embodiment, only the rotating members 51 that support the carrier 7 from the lower side in the vertical direction Z are illustrated, but another rotating member that supports the linear motor driving unit 43 from both sides in the horizontal direction may be provided.

### Configuration Example of Support Unit

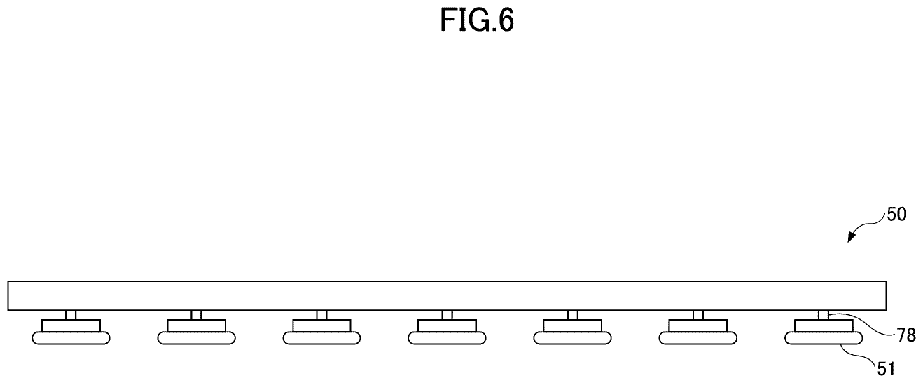

FIGS. 5 and 6 are a side view and a plan view of a support unit according to the embodiment. As illustrated in FIGS. 5 and 6, the transport mechanism 11 includes a support unit 50 provided in the chamber 5 and configured to support the carrier 7.

The support unit 50 includes a plurality of rotating members 51 that support the carrier 7, and extends from the upstream side to the downstream side in a transport direction of the carrier 7. In the present embodiment, seven rotating members 51 are provided in the support unit 50, but the number of the rotating members 51 is not limited.

The plurality of rotating members 51 are arranged in a row from the upstream side to the downstream side in the conveying direction of the carrier 7. The rotating members 51 support the carrier 7 in the chamber 5. The rotating members 51 come into contact with the supported surface 42 of the carrier 7 when the carrier 7 is conveyed. The positions of the upper ends of the plurality of rotating members 51 in the vertical direction Z are the same height positions. Herein, since the gate valve 6 is provided at the connection portion of each chamber 5, the support unit 50 is not provided at the position of the gate valve 6 in order to allow each gate valve 6 to open and close.

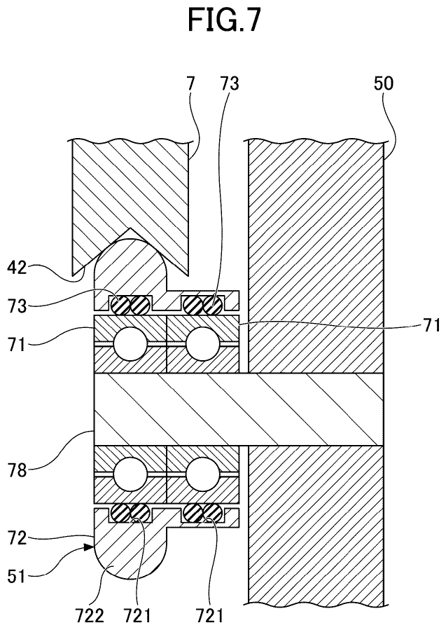

FIG. 7 is a cross-sectional view of the rotating member 51 in the support unit 50. The cross section illustrated in FIG. 7 is a cross section including the central axis of a support shaft 78. As illustrated in FIG. 7, bearings 71, buffer members 73, and a rotating member outer peripheral portion 72 are supported by the support shaft 78 of the support unit 50, and thus the rotating member 51 is supported by the support shaft 78 in a cantilever manner.

The rotating member 51 includes the rotating member outer peripheral portion 72 having an annular shape, the bearings 71 provided inside the rotating member outer peripheral portion 72, and the buffer members 73 provided between the inner peripheral surface of the rotating member outer peripheral portion 72 and the outer peripheral surfaces of the bearings 71. With this configuration, a moment applied to the buffer members 73 can be reduced. Therefore, according to the film-forming apparatus 1 of the present embodiment, it is possible to suppress the deformation of the buffer members 73 and maintain the positional accuracy of the rotating members 51.

Since the buffer members 73 are provided between the inner peripheral surface of the rotating member outer peripheral portion 72 and the outer peripheral surfaces of the bearings 71, it is not necessary to increase the stiffness of the buffer members 73. Therefore, the buffering property of the buffer members 73 can be maintained. Therefore, according to the film-forming apparatus 1, the buffer member 73 can reduce the vibration of the carrier 7 when the carrier 7 passes through the gate valve 6, and can suppress damage or fall of the substrate 9 held by the carrier 7. Specifically, when the carrier 7 is transported, the rotating member 51 is displaced mainly downward in the vertical direction Z with respect to the support unit 50. Therefore, according to the film-forming apparatus 1, the carrier 7 can be more smoothly transferred at the gate valve 6 between the chambers 5.

Furthermore, since the usable range of the stiffness of the buffer member 73 is widened, it is easy to select a buffer member that can be used in a vacuum environment or a buffer member having high heat resistance. Therefore, the degree of freedom in designing the film-forming apparatus 1 can be increased.

There is a case where buffer members are provided on a contact surface where a rotating member comes into contact with a carrier in a conventional film-forming apparatus; in such a case, however, the buffer members are easily worn, which requires a frequent replacement of the support unit and lowers the productivity, and the frequency of changing the support unit, and dust generated by the wear of the buffer members deteriorates a film forming environment. In addition, in a chamber in which the substrate is heated, the buffer members are easily damaged by heat. Therefore, in the conventional film-forming apparatus, the productivity is lowered due to the increased frequency of replacement of the rotating members, and the production cost is increased due to the necessity of using expensive buffer members having high heat resistance.

In the film-forming apparatus 1 of the present embodiment, since the buffer member 73 is covered with the rotating member outer peripheral portion 72, it is possible to reduce the wear of the buffer member 73 and the generation of dust, and to reduce the replacement frequency of the rotating members 51 and the bearings 71. Further, since the radiation heat applied to the buffer members 73 is reduced by the rotating member outer peripheral portion 72, the usable range of the buffer members 73 in terms of heat resistance is widened. For example, the buffer member 73 containing a general-purpose resin, such as a petroleum-based resin, a silicone-based resin, or a fluorine-based resin, can be used. In other words, the film-forming apparatus 1 can form a film under a vacuum environment or a heating environment. In particular, under a high vacuum environment or a heating environment at a high temperature, a fluorine-based resin is preferably used.

Two bearings 71 may be provided along an axial direction inside the rotating member outer peripheral portion 72, and a plurality of buffer members 73 may be provided so as to face the outer peripheral surfaces of the two bearings 71. With this configuration, the moment applied to one buffer member 73 can be further reduced. Therefore, according to the film-forming apparatus 1 of the present embodiment, it is possible to further suppress the deformation of the buffer members 73 and to further maintain the positional accuracy of the rotating members 51. According to the film-forming apparatus 1, the plurality of buffer members 73 can further reduce the vibration of the carrier 7 when the carrier 7 passes through the gate valve 6, and can further suppress the damage or the fall of the substrate 9 held by the carrier 7.

In the example illustrated in FIG. 7, two bearings 71 are provided inside the rotating member 51, and a series of two bearings 71 is rotatably attached to a support shaft 78. Further, four O-rings are used as the buffer members 73, and the four O-rings are fitted between the series of two bearings 71 and the rotating member outer peripheral portion 72.

The rotating member outer peripheral portion 72 has recessed portions 721 provided at an inner peripheral surface and accommodating the buffer members 73, and the rotating member 51 has a gap formed between the inner peripheral surface of the rotating member outer peripheral portion 72 and the outer peripheral surfaces of the bearings 71. In other words, the inner diameter of the rotating member outer peripheral portion 72 is larger than the outer diameters of the bearings 71. In addition, the buffer members 73 and the outer peripheral surfaces of the bearings 71 are in contact with each other. With this configuration, according to the film-forming apparatus 1, it is possible to further reduce the vibration of the carrier 7 when the carrier 7 passes through the gate valve 6, and to further suppress damage or fall of the substrate 9 held by the carrier 7.

For example, in the case where the outer diameter of the rotating member outer peripheral portion 72 is 50 mm and the outer diameter of the bearing 71 is 30 mm, the gap is about 0.1 mm or more and 0.5 mm or less. Herein, the outer diameter of each of the rotating member outer peripheral portion 72 and the bearing 71 means a maximum value. With such a configuration, contact between the rotating member outer peripheral portion 72 and the bearings 71 is prevented, and generation of dust due to wear of these components is reduced. Furthermore, since abrasion between the rotating member outer peripheral portion 72 and the buffer members 73 and abrasion between the bearings 71 and the buffer members 73 are not basically generated, abrasion between these components is prevented and generation of dust is reduced.

The buffer members 73 are an annular elastic member, and the recessed portions 721 may be formed in an annular shape. Thus, an elastic member is provided around between the inner peripheral surface of the rotating member outer peripheral portion 72 and the outer peripheral surfaces of the bearings 71. Therefore, according to the film-forming apparatus 1, the vibration of the carrier 7 when passing through the gate valve 6 can be further reduced. The inner diameter of the annular elastic member may be smaller than the inner diameter of the rotating member outer peripheral portion 72. Herein, the inner diameter of the rotating member outer peripheral portion 72 means the inner diameter of a portion excluding the recessed portions 721.

The rotating member outer peripheral portion 72 has an annular flange portion 722 provided at one end, and the buffer members 73 may be arranged at a position overlapping at least the flange portion 722 when viewed from the vertical direction Z. Thus, the flange portion 722 is brought into contact with the supported surface 42 of the carrier 7, and the buffer members 73 are arranged at positions where the buffer members 73 are likely to receive the load of the carrier 7. Therefore, according to the film-forming apparatus 1, the vibration of the carrier 7 when passing through the gate valve 6 can be further reduced.

The film-forming apparatus 1 can be suitably used in a case where the plurality of support members 13 are configured to abut on the outer peripheral edge portion of the substrate 9 and support the substrate 9 fitted into the hole portion 12.

Hereinafter, the embodiment will be described more specifically by way of examples.

### Example 1

The support unit illustrated in FIG. 7 was manufactured, a vibration sensor was attached to the carrier, and the support unit was mounted on the film formation apparatus illustrated in FIG. 1, and the film formation apparatus was operated. Then, the frequency of occurrence of vibration and the presence or absence of generation of dust were evaluated. Specifically, the vibration during the conveyance of the carrier was measured using a vibration meter, the waveform was extracted for each acceleration band, and the frequency of occurrence was expressed in a histogram. After the film-forming apparatus was operated for 336 hours, the first, second, and seventh rotating members from the upstream side in the conveying direction, that is, the rotating members to which an impact is particularly applied during operation were disassembled, and then the state of the O-rings as the buffer members was visually checked, and the buffer members were wiped with a cloth to check the presence or absence of dust.

### Comparative Example 1

A support unit was produced in the same manner as in Example 1, except that the buffer members were not provided between the inner peripheral surface of the outer peripheral portion of the rotating member and the outer peripheral surfaces of the bearings, and the support unit was mounted on a film-forming apparatus in the same manner as in Example 1, and then the film-forming apparatus was operated. Then, the same evaluation as in Example 1 was performed.

It was confirmed that the frequency of occurrence of the vertical accelerations of ±100 mm/sec² was reduced by half in the film-forming apparatus of Example 1 as compared with the film-forming apparatus of Comparative Example 1. In the film-forming apparatus of Example 1, no dust was generated from the first, second, and seventh rotating members, and no deterioration of the buffer member was observed.

Although the preferred embodiments have been described in detail, the present invention is not limited to the above-described embodiments, and various modifications and substitutions can be made to the above-described embodiments without departing from the scope of the appended claims.

For example, the film-forming apparatus of the present disclosure is not limited to the inline film-forming apparatus, and may be a film-forming apparatus of another form such as a batch-type film-forming apparatus. The substrate of the present disclosure is not limited to the substrate 9 for a magnetic recording medium, and may be a substrate for a semiconductor integrated circuit. The shape of the substrate of the present disclosure is not limited to a disk shape.

In addition, the numbers such as ordinal numbers, quantities, units, and ranges used in the description of the above-described embodiments are examples for specifically describing the technology of the present disclosure, and the present disclosure is not limited to the exemplified numbers. The connection relationship between the constituent elements is an example for specifically describing the technique of the present disclosure, and the connection relationship for realizing the functions of the present disclosure is not limited thereto.

What is claimed is:

1. A film-forming apparatus, comprising:
a carrier configured to hold a substrate;
a plurality of chambers configured to perform a film forming process on the substrate;
a vacuum pump configured to decompress an inside of at least one of the plurality of chambers;
a gate valve configured to make the chamber a sealed space; and
a transport mechanism configured to transport the carrier into the gate valve and the plurality of chambers, wherein
at least one of the plurality of chambers includes a heating mechanism for the substrate,
the transport mechanism includes a support unit provided in the chamber and configured to support the carrier,
the support unit includes a plurality of rotating members that support the carrier, and extends from an upstream side to a downstream side in a transport direction of the carrier,
the plurality of rotating members are arranged in a row from the upstream side to the downstream side of the support unit, and
each of the rotating members includes
a rotating member outer peripheral portion having an annular shape,
a bearing provided inside the rotating member outer peripheral portion, and
a buffer member provided between an inner peripheral surface of the rotating member outer peripheral portion and an outer peripheral surface of the bearing.

2. The film-forming apparatus according to claim 1, wherein
the rotating member outer peripheral portion has a recessed portion provided at the inner peripheral surface of the rotating member outer peripheral portion and configured to accommodate the buffer member,
each of the rotating members has a gap formed between the inner peripheral surface of the rotating member outer peripheral portion and the outer peripheral surface of the bearing, and
the buffer member and the outer peripheral surface of the bearing are in contact with each other.

3. The film-forming apparatus according to claim 2, wherein
two bearings are provided along an axial direction inside the rotating member outer peripheral portion, the two bearings being the bearing, and
a plurality of buffer members are provided in each of the two bearings so as to face respective outer peripheral surfaces of the two bearings, the respective outer peripheral surfaces being the outer peripheral surface of the bearing.

4. The film-forming apparatus according to claim 3, wherein
the buffer member is an annular elastic member, and the recessed portion is formed in an annular shape.

5. The film-forming apparatus according to claim 4, wherein
the rotating member outer peripheral portion has an annular flange portion provided at one end, the carrier has a supported surface supported by
the annular flange portion from a lower side in a vertical direction, and
the buffer member is arranged at a position overlapping at least the annular flange portion when viewed from the vertical direction.

6. The film-forming apparatus according to claim 5, wherein
the carrier includes
a substrate holder provided with a hole portion in which the substrate is arranged, and
a plurality of support members attached around the hole portion of the substrate holder in an elastically deformable manner, and
the plurality of support members abut on an outer peripheral edge portion of the substrate and support the substrate fitted into the hole.
